(19) United States
(12) Patent Application Publication
(10) Pub. No.: US 2015/0214886 A1
(43) Pub. Date: Jul. 30, 2015

(54) LIGHT GUIDE TAPE

(71) Applicant: BENQ MATERIALS CORPORATION, Taoyuan County (TW)

(72) Inventor: Fung-Hsu WU, Taoyuan County (TW)

(21) Appl. No.: 14/532,780

(22) Filed: Nov. 4, 2014

(30) Foreign Application Priority Data
Jan. 28, 2014 (TW) 103103137

(51) Int. Cl. H02S 40/22; H01L 31/02; C09J 133/00; C09J 7/02; C09J 183/00

(52) U.S. Cl. CPC H02S 40/22; C09J 7/026; C09J 183/00; C09J 133/00; H01L 31/0201; C09J 2203/322; C09J 2433/00; C09J 2483/00; C09J 2423/001; C09J 2431/001

(57) ABSTRACT

A light guide tape for using on bus bars of solar panels to increase the utilization efficiency of the incident sunlight is disclosed. The light guide tape includes a flexible transparent substrate with a plurality of light guide micro-structures on the side of the incident sunlight, and an adhesive layer. The incident sunlight shielded by the bus bars of the solar cells can transfer to generating regions of both sides of the bus bars through the plurality of light guide micro-structures to increase the utilization efficiency of the incident sunlight.

### CROSS-REFERENCE TO RELATED APPLICATION

This application claims the benefit of Taiwan Patent Application No. 103103137, filed on Jan. 28, 2014, in the Taiwan Intellectual Property Office, the disclosure of which is incorporated herein in its entirety by reference.

### BACKGROUND

1. Technical Field

The present invention relates to a light guide tape for using on bus bars of solar panels for transferring the incident sunlight to outside areas of the bus bars by single reflecting.

2. Description of Related Art

As the shortage of energy, the use of solar energy and other green energy are on the increase. However, the photoelectric conversion efficiency of currently commercially solar panels is only about 10% to 25%, which is not sufficient to substantially replace the existing energy use. Therefore, how to increase the efficiency of solar panels is a target that peoples are striving toward. There are bus bars on the conventional solar panels for collecting the current transformed from the incident sunlight; the more and the wider bus bar is, the less current is consumed during conducting. Unfortunately, the material of the bus bars is usually metal, and the incident sunlight cannot penetrate the bus bars. Accordingly, the larger area occupied by the bus bars will reduce more incident sunlight through the solar panels and will also decrease the efficiency of solar panels.

### SUMMARY OF THE INVENTION

Accordingly, the present disclosure is to provide a novel, inventive and useful light guide tape for adhering to the bus bars of solar panels in accordance with the number and distribution thereof; therefore, the incident sunlight shielded by the bus bars of the solar cells can transfer to generating regions of both sides of the bus bars to restore the original amount of power that can be generated in the generating regions to increase the utilization efficiency of the incident sunlight; furthermore, manufacturing process and structures of conventional solar panels do not need to change or redesign, because the light guide tapes are applied by adhering to the bus bars of the conventional solar panels, so as to be suitable for various sizes of the conventional solar panels without changing the original design of solar panels.

An aspect of the present disclosure is to provide a light guide tape comprising a flexible transparent substrate with a plurality of light guide micro-structures on the side of the incident sunlight; and an adhesive layer for adhering the light guide tape to the bus bars of the solar panels; wherein each of the light guide micro-structures is in a prism shape with a reflective surface for reflecting the incident sunlight, wherein the included angle between the reflective surface and the flexible transparent substrate is at 30 degree to 60 degree, preferably at 40 degree to 50 degree to transfer the incident sunlight to outside areas of the bus bars by single reflecting.

In a light guide tape of a preferred embodiment of the present invention, the height of each of the light guide micro-structures is in a range of 10 μm to 1000 μm, preferably in a range of 20 μm to 100 μm; the width of each of the light guide micro-structures is in a range of 10 μm to 1000 μm, preferably in a range of 20 μm to 100 μm; the pitch of the light guide micro-structures is in a range of 0 μm to 1000 μm, preferably in a range of 0 μm to 100 μm.

In a light guide tape of a preferred embodiment of the present invention, the plurality of light guide micro-structures include a plurality of metallic reflective coating or a plurality of light guide prism structures.

In a light guide tape of a preferred embodiment of the present invention, the reflective surfaces of the light guide micro-structures are facing to the same direction or opposite directions.

In a light guide tape of a preferred embodiment of the present invention, the included angles between the reflective surfaces and the flexible transparent substrate are the same or configured to vary in continuous angles.

In a light guide tape of a preferred embodiment of the present invention, the material of the flexible transparent substrate is selected from the group consisting of acrylic resin, polyester and polycarbonate.

In a light guide tape of a preferred embodiment of the present invention, the adhesive layer is silicone or acrylic adhesive.

In a light guide tape of a preferred embodiment of the present invention, the light guide tape further comprises a protective layer on the plurality of light guide micro-structures for enhancing the durability of the light guide tape; the material of the protective layer is selected from the group consisting of ethylene-vinyl acetate and polyolefin.

### BRIEF DESCRIPTION OF THE DRAWINGS

The accompanying drawings, which are incorporated herein and constitute part of this specification, illustrate example embodiments of the invention, and together with the general description given above and the detailed description given below, serve to explain the features of the invention.

FIG. 1 is a perspective view of the light guide tape of a preferred embodiment of the present invention;

FIGS. 2-1 to 2-2 are perspective views illustrating the light guide tapes of further preferred embodiments of the present invention;

FIGS. 3-1 to 3-2 are perspective views illustrating arrangements of the light guide micro-structures of the light guide tape of a preferred embodiment of the present invention;

### DESCRIPTION OF EMBODIMENTS OF THE INVENTION

To describe the technical features of the present invention in greater detail, preferred embodiments of the present invention are provided below along with the accompanied drawings accordingly as follows. The various embodiments will be described in detail with reference to the accompanying drawings. References made to particular examples and implementations are for illustrative purposes, and are not intended to limit the scope of the invention or the claims.

The light guide tape of the present invention will be described along with the accompanied drawings accordingly as follows. It is appreciated that the same reference numbers will be used throughout the drawings to refer to the same or like parts.

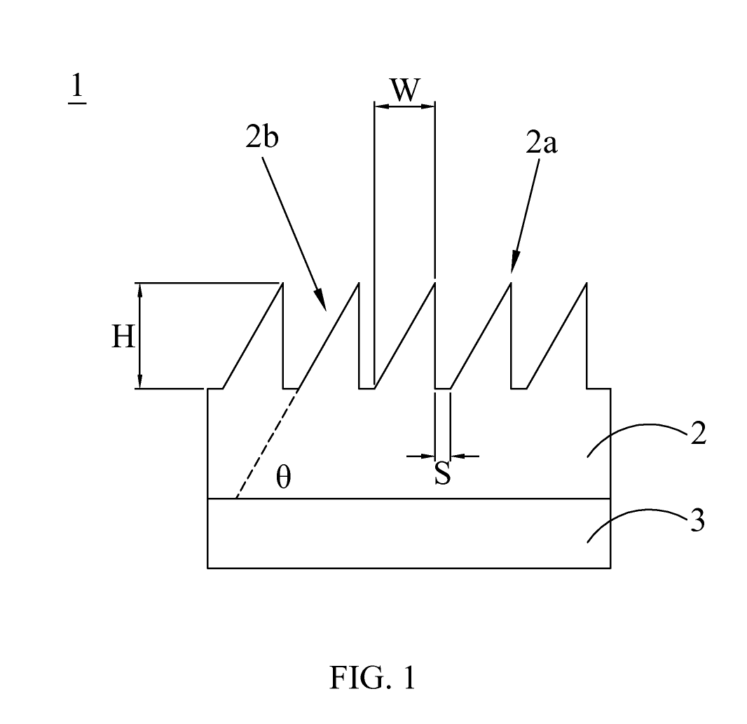

Referring to FIG. 1, an aspect of the present disclosure is to provide a light guide tape 1 comprising a flexible transparent substrate 2 with a plurality of light guide micro-structures 2a on the side of the incident sunlight, and an adhesive layer 3 on an opposite side to the flexible transparent substrate 2 with respect to the plurality of light guide micro-structures 2a for adhering the light guide tape 1 to the bus bars of the solar panels; wherein each of the light guide micro-structures 2a is in a prism shape with a reflective surface 2b for reflecting the incident sunlight, wherein the included angle θ between the reflective surface 2b and the flexible transparent substrate 2 is at 30 degree to 60 degree, preferably at 40 degree to 50 degree to transfer the incident sunlight to generating regions of both sides of the bus bars by single reflecting; accordingly, reducing the loss of incident sunlight during the transmission.

In a light guide tape of a preferred embodiment of the present invention, the height H of each of the light guide micro-structures 2a is in a range of 10 μm to 1000 μm, preferably in a range of 20 μm to 100 μm; the width W of each of the light guide micro-structures 2a is in a range of 10 μm to 1000 μm, preferably in a range of 20 μm to 100 μm; the pitch S of the light guide micro-structures 2a is in a range of 0 μm to 1000 μm, preferably in a range of 0 μm to 100 μm.

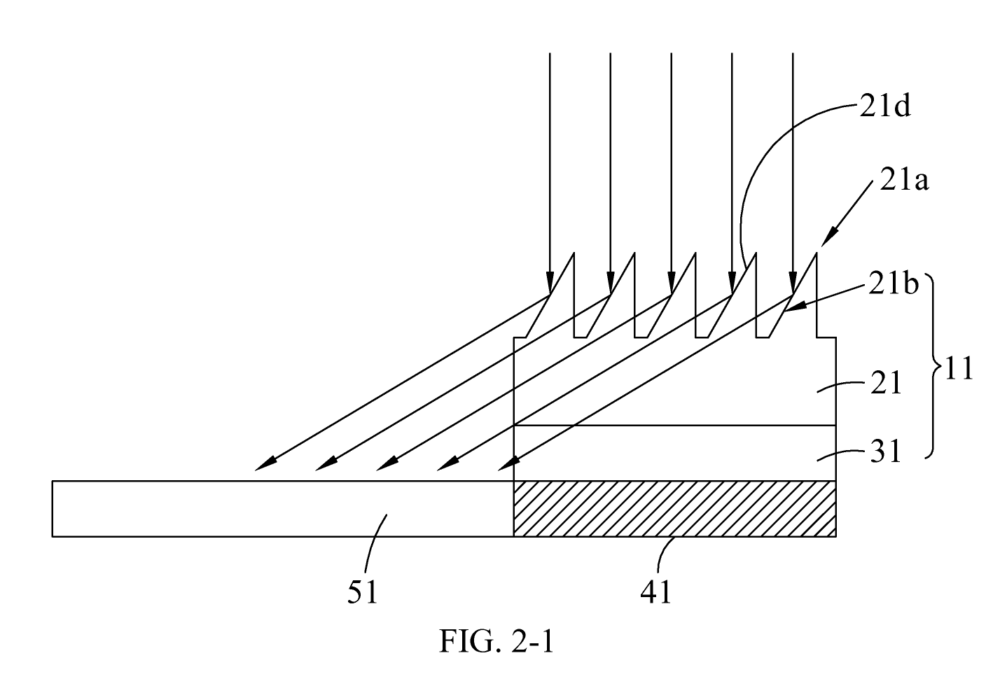

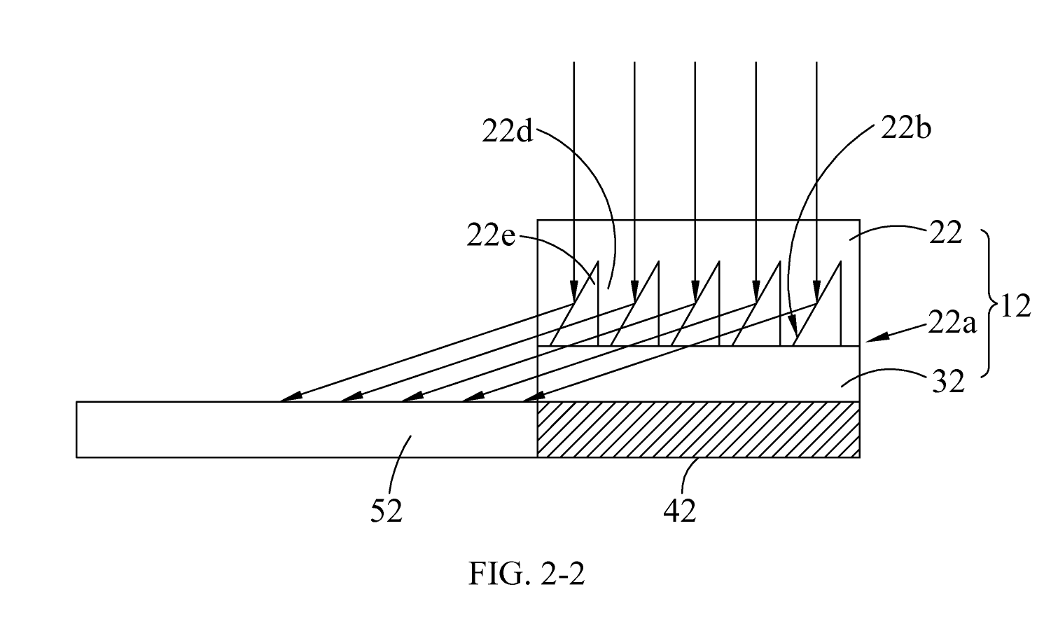

Referring to FIG. 2-1, in another aspect of the present disclosure, a light guide tape 11 is adhered to the bus bar 41 of the solar panel with an adhesive layer 31; the light guide tape 11 comprises a flexible transparent substrate 21 with a plurality of light guide micro-structures 21a; the plurality of light guide micro-structures 21a include metallic reflective coating for transferring the incident sunlight to generating regions 51 differed from the bus bar 41 by single reflecting, wherein the method for forming the metallic reflective coating, for example, is to coat metal layers 21d on reflective surfaces 21b; the material of the metal layers 21d is selected from the group consisting of silver, aluminum, chromium and copper.

Referring to FIG. 2-2, in another aspect of the present disclosure, a light guide tape 12 is adhered to the bus bar 42 of the solar panel; the light guide tape 12 comprises a flexible transparent substrate 22 with a plurality of light guide micro-structures 22a; the plurality of light guide micro-structures 22a include light guide prism structures 22d for transferring the incident sunlight to generating regions 52 differed from the bus bar 42 by single reflecting, and an adhesive layer 32 on the light guide prism structures 22d; there are interspaces 22e between the light guide prism structures 22d and the adhesive layer 32; therefore the incident sunlight can be totally-reflected by reflective surfaces 22b with proper refractive index of the light guide prism structures 22d. In this case, the light guide prism structures 22d can be with flat top surfaces in order to be more conveniently adhered to the adhesive layer 32.

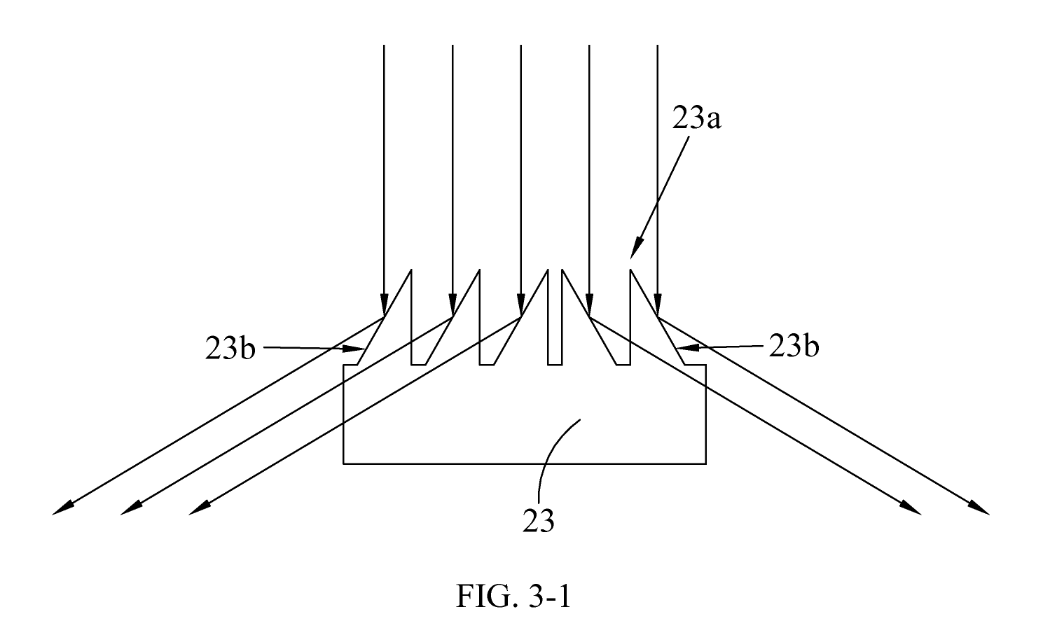

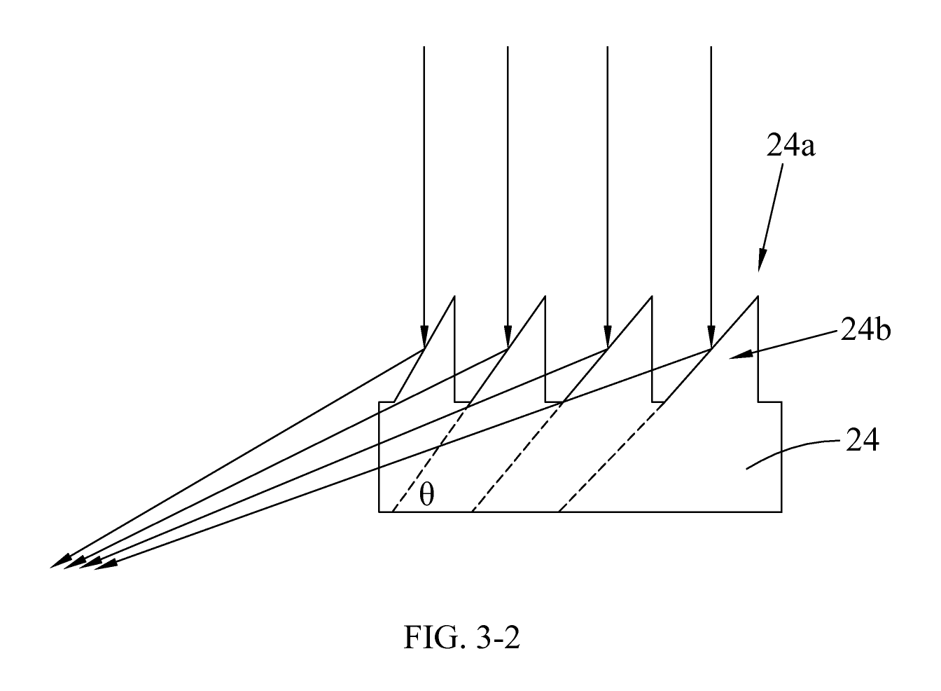

Referring to FIG. 3-1, in a light guide tape of a preferred embodiment of the present invention, the reflective surfaces 23b of the light guide micro-structures 23a on the flexible transparent substrate 23 are facing to the same direction or opposite directions.

Referring to FIG. 3-2, in a light guide tape of another preferred embodiment of the present invention, the included angles θ between the reflective surface 24b of the light guide micro-structures 24a and the flexible transparent substrate 24 are the same or configured to vary in continuous angles for further controlling the emergent angle of the incident sunlight, and the proportion of the incident sunlight penetrating the flexible transparent substrate 24 can be reduced for decreasing the loss of the incident sunlight during the transmission.

In a light guide tape of another preferred embodiment of the present invention, the material of the flexible transparent substrate is selected from the group consisting of acrylic resin, polyester and polycarbonate.

In a light guide tape of another preferred embodiment of the present invention, the adhesive layer is silicone or acrylic adhesive.

In a light guide tape of another preferred embodiment of the present invention, the light guide tape further comprises a protective layer on the plurality of light guide micro-structures for increasing the durability of the light guide tape; the material of the protective layer is selected from the group consisting of ethylene-vinyl acetate and polyolefin.

In summary, after the light guide tape of the present invention being adhered to the bus bar of the solar panel, the incident sunlight shielded by the bus bars of the solar cells can transfer to the generating regions outside the areas of the bus bars to restore the original amount of power that can be generated to increase the utilization efficiency of the incident sunlight; furthermore, the design of the light guide tape allows to transfer the incident sunlight to the generating regions of both sides of the bus bars by single reflecting, which is not multi-reflecting or multi-refracting, and accordingly reduces the loss of incident sunlight during the transmission.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light guide tape for using on bus bars of solar panels comprising:
a flexible transparent substrate with a plurality of light guide micro-structures on the side of incident sunlight; and
an adhesive layer for adhering the light guide tape to the bus bars of the solar panels;
wherein each of the light guide micro-structures is in a prism shape with a reflective surface for reflecting the incident sunlight, wherein an included angle between each of the reflective surfaces and the flexible transparent substrate is at 30 degree to 60 degree to transfer the incident sunlight to outside areas of the bus bars by single reflecting.

2. The light guide tape according to claim 1, wherein the included angle between the reflective surface and the flexible transparent substrate is at 40 degree to 50 degree.

3. The light guide tape according to claim 1, wherein the plurality of light guide micro-structures include a plurality of metallic reflective coating or a plurality of light guide prism structures.

4. The light guide tape according to claim 1, wherein the height of each of the light guide micro-structures is in a range of 10 μm to 1000 μm.

5. The light guide tape according to claim 4, wherein the height of each of the light guide micro-structures is in a range of 20 μm to 100 μm.

6. The light guide tape according to claim 1, wherein the width of each of the light guide micro-structures is in a range of 10 μm to 1000 μm.

7. The light guide tape according to claim 6, wherein the width of each of the light guide micro-structures is in a range of 20 μm to 100 μm.

8. The light guide tape according to claim 1, wherein the pitch of the light guide micro-structures is in a range of 0 μm to 1000 μm.

9. The light guide tape according to claim 8, wherein the pitch of the light guide micro-structures is in a range of 0 μm to 100 μm.

10. The light guide tape according to claim 1, wherein the reflective surfaces of the light guide micro-structures are facing to the same direction or opposite directions.

11. The light guide tape according to claim 1, wherein the included angles between the reflective surfaces and the flexible transparent substrate are the same or configured to vary in continuous angles.

12. The light guide tape according to claim 1, wherein the material of the flexible transparent substrate is selected from the group consisting of acrylic resin, polyester and polycarbonate.

13. The light guide tape according to claim 1, wherein the adhesive layer is silicone or acrylic adhesive.

14. The light guide tape according to claim 1, further comprising a protective layer on the plurality of light guide micro-structures for increasing the durability of the light guide tape.

15. The light guide tape according to claim 14, wherein the material of the protective layer is selected from the group consisting of ethylene-vinyl acetate and polyolefin.
